(19) United States
(12) Patent Application Publication
(10) Pub. No.: US 2013/0244922 A1
(43) Pub. Date: Sep. 19, 2013

(54) AZEOTROPIC COMPOSITIONS COMPRISING METHYL PERFLUOROPENTENE ETHERS FOR CLEANING APPLICATIONS

(71) Applicants: Joan Ellen Bartelt, Wilmington, DE (US); Barbara Haviland Minor, Elkton, MD (US)

(72) Inventors: Joan Ellen Bartelt, Wilmington, DE (US); Barbara Haviland Minor, Elkton, MD (US)

(73) Assignee: E I DU PONT DE NEMOURS AND COMPANY, Wilmington, DE (US)

(21) Appl. No.: 13/609,857

(22) Filed: Sep. 11, 2012

Related U.S. Application Data
(60) Provisional application No. 61/533,855, filed on Sep. 13, 2011.

(51) Int. Cl. C11D 7/50; C11D 11/00; H01L 21/02; C09D 7/00

(52) U.S. Cl. CPC C11D 7/5068; C09D 7/001; C11D 7/5063; C11D 11/0005; H01L 21/02104
USPC 510/409; 252/364; 510/410; 510/411; 134/31; 427/372.2; 427/127; 438/758

(57) ABSTRACT

The present disclosure provides azeotropic and azeotrope-like compositions comprised of methylperfluoropentene ethers and at least one of methanol, ethanol, 2-propanol, hexane, heptane, trans-1,2-dichloroethylene, ethyl formate, methyl formate, HFE-7100, HFE-7200 and 1-bromopropane or combinations thereof. The present disclosure also provides for methods of use for the azeotropic and azeotrope-like compositions.

### CROSS REFERENCE(S) TO RELATED APPLICATION(S)

This application claims the benefit of priority of U.S. Provisional Applications 61/533,855, filed Sep. 13, 2011

### BACKGROUND INFORMATION

1. Field of the Disclosure

This disclosure relates in general to compositions comprising methyl perfluoropentene ethers. These compositions are azeotropic or azeotrope-like and are useful in cleaning applications as a defluxing agent and for removing oils or residues from a surface.

2. Description of the Related Art

Flux residues are always present on microelectronics components assembled using rosin flux. As modern electronic circuit boards evolve toward increased circuit and component densities, thorough board cleaning after soldering becomes a critical processing step. After soldering, the flux-residues are often removed with an organic solvent. De-fluxing solvents should be non-flammable, have low toxicity and have high solvency power, so that the flux and flux-residues can be removed without damaging the substrate being cleaned. For proper operation in use, microelectronic components must be cleaned of flux residues, oils and greases, and particulates that may contaminate the surfaces after completion of manufacture.

In cleaning apparatuses, including vapor degreasing and vapor defluxing equipment, compositions may be lost during operation through leaks in shaft seals, hose connections, soldered joints and broken lines. In addition, the working composition may be released to the atmosphere during maintenance procedures on equipment. If the composition is not a pure component, the composition may change when leaked or discharged to the atmosphere from the equipment, which may cause the composition remaining in the equipment to exhibit unacceptable performance. Accordingly, it is desirable to use a composition comprising a single unsaturated fluorinated ether as a cleaning composition.

Alternative, non-ozone depleting solvents have become available since the elimination of nearly all previous chlorofluorocarbons (CFCs) and hydrochlorofluorocarbons (HCFCs) as a result of the Montreal Protocol. While boiling point, flammability and solvent power characteristics can often be adjusted by preparing solvent mixtures, these mixtures are often unsatisfactory because they fractionate to an undesirable degree during use. Such solvent mixtures also fractionate during solvent distillation, which makes it virtually impossible to recover a solvent mixture of the original composition.

Many industries use aqueous compositions for the surface treatment of metals, ceramics, glasses, and plastics. Cleaning, plating, and deposition of coatings are often carried out in aqueous media and are usually followed by a step in which residual water is removed. Hot air drying, centrifugal drying, and solvent-based water displacement are methods used to remove such residual water.

There is a need in the industry for improved methods for deposition of fluorolubricants. The use of certain solvents, such as CFC-113 and PFC-5060, has been regulated due to their impact on the environment. While hydrofluorocarbons (HFCs) have been proposed as replacements for the previously used CFC solvents in drying or dewatering applications, many HFCs have limited solvency for water. The use of surfactant, which assists in removal of water from substrates, is therefore necessary in many drying or dewatering methods. Hydrophobic surfactants have been added to dewatering or drying solvents to displace water from substrates.

The primary function of the dewatering or drying solvent (unsaturated fluorinated ether solvent) in a dewatering or drying composition is to reduce the amount of water on the surface of a substrate being dried. The primary function of the surfactant is to displace any remaining water from the surface of the substrate. When the unsaturated fluorinated ether solvent and surfactant are combined, a highly effective displacement drying composition is attained.

Solvents used for this purpose must dissolve the fluorolubricant and form a substantially uniform or uniform coating of fluorolubricant. Additionally, existing solvents have been found to require higher fluorolubricant concentrations to produce a given thickness coating and produce irregularities in uniformity of the fluorolubricant coating.

The most advanced, highest recording densities and lowest cost method of storing digital information involves writing and reading magnetic flux patterns from rotating disks coated with magnetic materials. A magnetic layer, where information is stored in the form of bits, is sputtered onto a metallic support structure. Next an overcoat, usually a carbon-based material, is placed on top of the magnetic layer for protection and finally a lubricant is applied to the overcoat. A read-write head flies above the lubricant and the information is exchanged between the head and the magnetic layer. The distance between the read-write head and the magnetic layer is less than 100 Angstroms.

Invariably, during normal disk drive application, the head and the disk surface will make contact. The disk is lubricated to reduce wear from sliding and flying contacts. Fluorolubricants are used as lubricants to decrease the friction between the head and disk, thereby reducing wear and minimizing the possibility of disk failure.

Azeotropic solvent mixtures may possess the properties needed for de-fluxing, de-greasing applications and other cleaning agent needs. Azeotropic mixtures exhibit either a maximum or a minimum boiling point and do not fractionate on boiling. The inherent invariance of composition under boiling conditions insures that the ratios of the individual components of the mixture will not change during use and that solvency properties will remain constant as well.

The present disclosure provides azeotropic and azeotrope-like compositions useful in semiconductor chip and circuit board cleaning, defluxing, and degreasing processes. The present compositions are non-flammable, and as they do not fractionate, will not produce flammable compositions during use. Additionally, the used azeotropic solvent mixtures may be re-distilled and re-used without composition change.

### SUMMARY

The present disclosure provides an azeotropic or azeotrope-like composition comprising methylperfluoropentene ethers (“MPPE”) and at least one of methanol, ethanol, 2-propanol, hexane, heptane, trans-1,2-dichloroethylene, ethyl formate, methyl formate, HFE-7100, HFE-7200 and 1-bromopropane or combinations thereof. The present disclosure further provides a method for removing residue from a surface of an article comprising: (a) contacting the article with a composition comprising an azeotropic or azeotrope-like composition of MPPE and at least one of methanol, ethanol, 2-propanol, hexane, heptane, trans-1,2-dichloroethylene, ethyl formate, methyl formate, HFE-7100, HFE-7200 and 1-bromopropane or combinations thereof; and (b) recovering the surface from the composition.

The present disclosure also provides a method for depositing a fluorolubricant onto a surface of an article comprising: (a) combining a fluorolubricant and a solvent, thereby forming a mixture, wherein the solvent comprises an azeotropic or azeotrope-like composition of MPPE and at least one of methanol, ethanol, 2-propanol, hexane, heptane, trans-1,2-dichloroethylene, ethyl formate, methyl formate, HFE-7100, HFE-7200 and 1-bromopropane or combinations thereof; (b) contacting the mixture with the surface of the article; and (c) evaporating the solvent from the surface of the article to form a fluorolubricant coating on the surface.

The foregoing general description and the following detailed description are exemplary and explanatory only and are not restrictive of the invention, as defined in the appended claims.

### DETAILED DESCRIPTION

Disclosed herein are azeotropic or azeotrope-like compositions comprising methyl perfluoropentene ethers and at least one of methanol, ethanol, 2-propanol, hexane, heptane, trans-1,2-dichloroethylene, ethyl formate, methyl formate, HFE-7100, HFE-7200 and 1-bromopropane or combinations thereof. Also disclosed herein are azeotropic or azeotrope-like compositions consisting essentially of methyl perfluoropentene ethers and at least one of methanol, ethanol, 2-propanol, hexane, heptane, trans-1,2-dichloroethylene, ethyl formate, methyl formate, HFE-7100, HFE-7200 and 1-bromopropane or combinations thereof.

Also disclosed herein are processes for cleaning comprising a residue with one of the azeotropic or azeotrope-like MPPE compositions above and removing the surface from the composition. Also disclosed are methods of depositing a lubricant on the surface of an article comprising combining a fluorolubricant and one of the azeotropic or azeotrope-like MPPE compositions above, contacting said mixture with the surface of an article, and evaporating the solvent from the surface of said article to form a fluorolubricant coating on the surface.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims.

As used herein, an azeotropic composition is a constant boiling liquid admixture of two or more substances wherein the admixture distills without substantial composition change and behaves as a constant boiling composition. Constant boiling compositions, which are characterized as azeotropic, exhibit either a maximum or a minimum boiling point, as compared with that of the non-azeotropic mixtures of the same substances. Azeotropic compositions as used herein include homogeneous azeotropes which are liquid admixtures of two or more substances that behave as a single substance, in that the vapor, produced by partial evaporation or distillation of the liquid, has the same composition as the liquid. Azeotropic compositions as used herein also include heterogeneous azeotropes where the liquid phase splits into two or more liquid phases. In these embodiments, at the azeotropic point, the vapor phase is in equilibrium with two liquid phases and all three phases have different compositions. If the two equilibrium liquid phases of a heterogeneous azeotrope are combined and the composition of the overall liquid phase calculated, this would be identical to the composition of the vapor phase.

As used herein, the term “azeotrope-like composition” also sometimes referred to as “near azeotropic composition,” means a constant boiling, or substantially constant boiling liquid admixture of two or more substances that behaves as a single substance. One way to characterize an azeotrope-like composition is that the vapor produced by partial evaporation or distillation of the liquid has substantially the same composition as the liquid from which it was evaporated or distilled. That is, the admixture distills/refluxes without substantial composition change. Another way to characterize an azeotrope-like composition is that the bubble point vapor pressure of the composition and the dew point vapor pressure of the composition at a particular temperature are substantially the same. Herein, a composition is azeotrope-like if, after 50 weight percent of the composition is removed such as by evaporation or boiling off, the difference in vapor pressure between the original composition and the composition remaining after 50 weight percent of the original composition has been removed by evaporation or boil off is less than 10 percent.

Described herein are azeotropic and azeotrope-like compositions of MPPE and at least one of methanol, ethanol, 2-propanol, hexane, heptane, trans-1,2-dichloroethylene, ethyl formate, methyl formate, HFE-7100, HFE-7200 and 1-bromopropane or combinations thereof. MPPE is described in pending U.S. patent application Ser. No. 12/701,802, the disclosure of which is herein incorporated by reference. Also described herein are novel methods of using an azeotropic or azeotrope-like composition comprising MPPE and at least one of methanol, ethanol, 2-propanol, hexane, heptane, trans-1,2-dichloroethylene, ethyl formate, methyl formate, HFE-7100, HFE-7200 and 1-bromopropane or combinations thereof.

A composition of one embodiment of the invention comprises MPPE and an effective amount of at least one of methanol, ethanol, 2-propanol, hexane, heptane, trans-1,2-dichloroethylene, ethyl formate, methyl formate, HFE-7100, HFE-7200 and 1-bromopropane or combinations thereof to form an azeotropic composition. An “effective amount” is defined as an amount which, when combined with MPPE, results in the formation of an azeotropic or near-azeotropic mixture. MPPE comprises isomeric mixtures of unsaturated fluoroethers which are the products of the reaction of perfluoropentenes such as perfluoro-2-pentene with methanol in the presence of a strong base. In one embodiment, the mixture comprises a mixture of one or more of the following compounds: CF₃CF═CFCF(OR) CF₃, CF₃C(OR)=CFCF₂CF₃, CF₃CF═CFCF(OR) CF₃, and CF₃CF═C(OR)CF₂CF₃; wherein R═CH₃.

Compositions may be formed that comprise azeotropic combinations MPPE and at least one of methanol, ethanol, 2-propanol, hexane, heptane, trans-1,2-dichloroethylene, ethyl formate, methyl formate, HFE-7100, HFE-7200 and 1-bromopropane or combinations thereof. The normal boiling point of MPPE is 75° C.

In another embodiment, compositions may be formed that consist essentially of azeotropic combinations MPPE and at least one of methanol, ethanol, 2-propanol, hexane, heptane, trans-1,2-dichloroethylene, ethyl formate, methyl formate, HFE-7100, HFE-7200 and 1-bromopropane or combinations thereof.

In one embodiment, the azeotropic compositions disclosed comprise the compositions listed in Table 1.

TABLE 1

| Comp A | Comp B | wt % A | wt % B | Bp (T ° C.) |
|---|---|---|---|---|
| MPPE | t-DCE | 37.7 | 62.3 | 43.3 |
| MPPE | Methanol | 87.1 | 12.9 | 51.0 |
| MPPE | Ethanol | 88.9 | 11.1 | 57.7 |
| MPPE | 2-propanol | 87.9 | 12.2 | 59.7 |
| MPPE | Cyclopentane | 18.4 | 81.6 | 49.1 |
| MPPE | Ethyl formate | 54.7 | 45.3 | 46.3 |
| MPPE | Methyl formate | 42.2 | 57.8 | 29.2 |
| MPPE | 1-bromopropane | 62.8 | 37.2 | 57.3 |

In another embodiment, the azeotropic compositions disclosed consist essentially of the compositions listed in Table 1. In another embodiment, the azeotrope-like compositions comprise the compositions listed in Table 2.

TABLE 2

| Comp A | Comp B | wt % A | wt % B |
|---|---|---|---|
| MPPE | t-DCE | 14-68 | 32-86 |
| MPPE | Methanol | 72-95 | 5-28 |
| MPPE | Ethanol | 72-96 | 4-28 |
| MPPE | 2-propanol | 70-95 | 5-30 |
| MPPE | Heptane | 1-15 | 85-99 |
| MPPE | Heptane | 76-99 | 1-24 |
| MPPE | Hexane | 1-99 | 1-99 |
| MPPE | Cyclopentane | 1-73 | 27-99 |
| MPPE | Ethyl formate | 33-79 | 21-67 |
| MPPE | Methyl formate | 26-79 | 21-74 |
| MPPE | HFE-7100 | 1-99 | 1-99 |
| MPPE | HFE-7200 | 1-99 | 1-99 |
| MPPE | 1-bromopropane | 39-83 | 17-61 |

In another embodiment, the azeotrope-like compositions consist essentially of the compositions listed in Table 2.

In yet another embodiment, the compositions disclosed comprise the ternary azeotrope compositions listed in Table 3. In yet another embodiment, the compositions disclosed consist essentially of the compositions listed in Table 3.

TABLE 3

| | | | | | | BP |
|---|---|---|---|---|---|---|
| Comp A | Comp B | Comp C | Wt % A | Wt % B | Wt % C | (T ° C.) |
| MPPE | t-DCE | 2-propanol | 38.8 | 58.4 | 2.8 | 42.9 |
| MPPE | t-DCE | ethanol | 39.1 | 26.7 | 4.2 | 41.9 |
| MPPE | t-DCE | methanol | 38.0 | 54.7 | 7.3 | 37.7 |

In yet another embodiment, the compositions disclosed comprise the ternary azeotrope-like compositions listed in Table 4. In another embodiment, the compositions disclosed consist essentially of the ternary azeotrope-like compositions listed in Table 4.

TABLE 4

| Comp A | Comp B | Comp C | Wt % A | Wt % B | Wt % C |
|---|---|---|---|---|---|
| MPPE | t-DCE | 2-propanol | 20-70 | 27-79 | 1-15 |
| MPPE | t-DCE | Ethanol | 20-70 | 27-79 | 1-15 |
| MPPE | t-DCE | Methanol | 25-70 | 25-70 | 3-15 |
| MPPE | t-DCE | HFE-7200 | 1-65 | 31-98 | 1-65 |
| MPPE | HFC-365mfc | t-DCE | 1-65 | 1-80 | 15-80 |

In one embodiment, the present compositions may further comprise a propellant. Aerosol propellant may assist in delivering the present composition from a storage container to a surface in the form of an aerosol. Aerosol propellant is optionally included in the present composition in up to about 25 weight percent of the total composition. Representative aerosol propellants comprise air, nitrogen, carbon dioxide, 2,3,3,3-tetrafluoropropene (HFO-1234yf), trans-1,3,3,3-tetrafluoropropene (HFO-1234ze), 1,2,3,3,3-pentafluoropropene (HFO-1225ye), difluoromethane (CF₂H₂, HFC-32), trifluoromethane (CF₃H, HFC-23), difluoroethane (CHF₂CH₃, HFC-152a), trifluoroethane (CH₃CF₃, HFC-143a; or CHF₂CH₂F, HFC-143), tetrafluoroethane (CF₃CH₂F, HFC-134a; or CF₂HCF₂H, HFC-134), pentafluoroethane (CF₃CF₂H, HFC-125), and hydrocarbons, such as propane, butanes, or pentanes, dimethyl ether, or combinations thereof.

In another embodiment, the present compositions may further comprise at least one surfactant. The surfactants of the present disclosure include all surfactants known in the art for dewatering or drying of substrates. Representative surfactants include alkyl phosphate amine salts (such as a 1:1 salt of 2-ethylhexyl amine and isooctyl phosphate); ethoxylated alcohols, mercaptans or alkylphenols; quaternary ammonium salts of alkyl phosphates (with fluoroalkyl groups on either the ammonium or phosphate groups); and mono- or di-alkyl phosphates of fluorinated amines. Additional fluorinated surfactant compounds are described in U.S. Pat. No. 5,908,822, incorporated herein by reference.

The amount of surfactant included in the dewatering compositions of the present invention can vary widely depending on the particular drying application in which the composition will be used, but is readily apparent to those skilled in the art. In one embodiment, the amount of surfactant dissolved in the unsaturated fluorinated ether solvent is not greater than about 1 weight percent, based on the total weight of the surfactant/solvent composition. In another embodiment, larger amounts of surfactant can be used, if after treatment with the composition, the substrate being dried is thereafter treated with solvent containing either no or minimal surfactant. In one embodiment, the amount of surfactant is at least about 50 parts per million (ppm, on a weight basis). In another embodiment, the amount of surfactant is from about 100 to about 5000 ppm. In yet another embodiment, the amount of surfactant used is from about 200 to about 2000 ppm based on the total weight of the dewatering composition.

Optionally, other additives may be included in the present compositions comprising solvents and surfactants for use in dewatering. Such additives include compounds having antistatic properties; the ability to dissipate static charge from non-conductive substrates such as glass and silica. Use of an antistatic additive in the dewatering compositions of the present invention may be necessary to prevent spots and stains when drying water or aqueous solutions from electrically non-conductive parts such as glass lenses and mirrors. Most unsaturated fluoroether solvents of the present invention also have utility as dielectric fluids, i.e., they are poor conductors of electric current and do not easily dissipate static charge.

Boiling and general circulation of dewatering compositions in conventional drying and cleaning equipment can create static charge, particularly in the latter stages of the drying process where most of the water has been removed from a substrate. Such static charge collects on non-conductive surfaces of the substrate and prevents the release of water from the surface. The residual water dries in place resulting in undesirable spots and stains on the substrate. Static charge remaining on substrates can bring out impurities from the cleaning process or can attract impurities such as lint from the air, which results in unacceptable cleaning performance.

In one embodiment, desirable antistatic additives are polar compounds, which are soluble in the present unsaturated fluorinated ether solvent and result in an increase in the conductivity of the unsaturated fluorinated ether solvent resulting in dissipation of static charge from a substrate. In another embodiment, the antistatic additives have a normal boiling point near that of the unsaturated fluorinated ether solvent and have minimal to no solubility in water. In yet another embodiment, the antistatic additives have a solubility in water of less than about 0.5 weight percent. In one embodiment, the solubility of antistatic agent is at least 0.5 weight percent in unsaturated fluorinated ether solvent. In one embodiment, the antistatic additive is nitromethane (CH₃NO₂).

In one embodiment, the dewatering composition containing an antistatic additive is effective in both the dewatering and drying and rinse steps of a method to dewater or dry a substrate as described below.

Another embodiment relates to a method for dewatering or drying a substrate comprising:
a) contacting the substrate with a composition comprising a solvent, wherein the solvent comprises an azeotropic or azeotrope-like composition of MPPE and at least one of methanol, ethanol, 2-propanol, hexane, heptane, trans-1,2-dichloroethylene, ethyl formate, methyl formate, HFE-7100, HFE-7200 and 1-bromopropane or combinations thereof, containing surfactant, thereby dewatering the substrate; and
b) recovering the dewatered substrate from the composition.

In one embodiment, the surfactant for dewatering and drying is soluble to at least 1 weight percent based on the total solvent/surfactant composition weight. In another embodiment, the dewatering or drying method of the present disclosure is very effective in displacing water from a broad range of substrates including metals, such as tungsten, copper, gold, beryllium, stainless steel, aluminum alloys, brass and the like; from glasses and ceramic surfaces, such as glass, sapphire, borosilicate glass, alumina, silica such as silicon wafers used in electronic circuits, fired alumina and the like; and from plastics such as polyolefin (“Alathon”, Rynite®, “Tenite”), polyvinylchloride, polystyrene (Styron), polytetrafluoroethylene (Teflon®), tetrafluoroethylene-ethylene copolymers (Tefzel®), polyvinylidenefluoride (“Kynar”), ionomers (Surlyn®), acrylonitrile-butadiene-styrene polymers (Kralac®), phenol-formaldehyde copolymers, cellulosic (“Ethocel”), epoxy resins, polyacetal (Delrin®), poly(p-phenylene oxide) (Noryl®), polyetherketone (“Ultrapek”), polyetheretherketone (“Victrex”), poly(butylene terephthalate) (“Valox”), polyarylate (Arylon®), liquid crystal polymer, polyimide (Vespel®), polyetherimides (“Ultem”), polyamideimides (“Torlon”), poly(p-phenylene sulfide) (“Rython”), polysulfone (“Udel”), and polyaryl sulfone (“Rydel”). In another embodiment, the compositions for use in the present dewatering or drying method are compatible with elastomers.

In one embodiment, the disclosure is directed to a process for removing at least a portion of water from the surface of a wetted substrate (dewatering), which comprises contacting the substrate with the aforementioned dewatering composition, and then removing the substrate from contact with the dewatering composition. In another embodiment, water originally bound to the surface of the substrate is displaced by solvent and/or surfactant and leaves with the dewatering composition. As used herein, the term “at least a portion of water” means at least about 75 weight percent of water at the surface of a substrate is removed per immersion cycle. As used herein, the term “immersion cycle” means one cycle involving at least a step wherein substrate is immersed in the present dewatering composition.

Optionally, minimal amounts of surfactant remaining adhered to the substrate can be further removed by contacting the substrate with surfactant-free halocarbon solvent. Holding the article in the solvent vapor or refluxing solvent will further decrease the presence of surfactant remaining on the substrate. Removal of solvent adhering to the surface of the substrate is effected by evaporation. Evaporation of solvent at atmospheric or subatmospheric pressures can be employed and temperatures above and below the boiling point of the halocarbon solvent can be used.

Methods of contacting the substrate with dewatering composition are not critical and can vary widely. For example, the substrate can be immersed in the composition, or the substrate can be sprayed with the composition using conventional equipment. Complete immersion of the substrate is preferred as it generally insures contact between the composition and all exposed surfaces of the substrate. However, any other method, which can easily provide such complete contact may be used.

The time period over which substrate and dewatering composition are contacted can vary widely. Usually, the contacting time is up to about 5 minutes, however, longer times may be used if desired. In one embodiment of the dewatering process, the contacting time is from about 1 second to about 5 minutes. In another embodiment, the contacting time of the dewatering process is from about 15 seconds to about 4 minutes.

Contacting temperatures can also vary widely depending on the boiling point of the composition. In general, the contacting temperature is equal to or less than the composition's normal boiling point.

In one embodiment, the compositions of the present disclosure may further contain a co-solvent. Such co-solvents are desirable where the present compositions are employed in cleaning conventional process residue from substrates, e.g., removing soldering fluxes and degreasing mechanical components comprising substrates of the present invention. Such co-solvents include alcohols (such as methanol, ethanol, isopropanol), ethers (such as diethyl ether, methyl tertiary-butyl ether), ketones (such as acetone), esters (such as ethyl acetate, methyl dodecanoate, isopropyl myristate and the dimethyl or diisobutyl esters of succinic, glutaric or adipic acids or mixtures thereof), ether alcohols (such as propylene glycol monopropyl ether, dipropylene glycol monobutyl ether, and tripropylene glycol monomethyl ether), and hydrocarbons (such as pentane, cyclopentane, hexane, cyclohexane, heptane, octane), and hydrochlorocarbons (such as trans-1,2-dichloroethylene). When such a co-solvent is employed with the present composition for substrate dewatering or cleaning, it may be present in an amount of from about 1 weight percent to about 50 weight percent based on the weight of the overall composition.

Another embodiment of the disclosure relates to a method of cleaning a surface comprising:
a. contacting the surface with a composition comprising a solvent, wherein the solvent comprises an azeotropic or azeotrope-like composition of MPPE and at least one of methanol, ethanol, 2-propanol, hexane, heptane, trans-1,2-dichloroethylene, ethyl formate, methyl formate, HFE-7100, HFE-7200 and 1-bromopropane or combinations thereof, and
b. recovering the surface from the composition.

In one embodiment, the compositions of the invention are useful as cleaning compositions, cleaning agents, deposition solvents and as dewatering or drying solvents. In another embodiment, the invention relates to a process for removing residue from a surface or substrate comprising contacting the surface or substrate with a cleaning composition or cleaning agent of the present disclosure and, optionally, recovering the surface or substrate substantially free of residue from the cleaning composition or cleaning agent.

In yet another embodiment, the present disclosure relates to a method for cleaning surfaces by removing contaminants from the surface. The method for removing contaminants from a surface comprises contacting the surface having contaminants with a cleaning composition of the present invention to solubilize the contaminants and, optionally, recovering the surface from the cleaning composition. The surface is then substantially free of contaminants. As stated previously, the contaminants or residues that may be removed by the present method include, but are not limited to oils and greases, flux residues, and particulate contaminants.

In one embodiment of the present disclosure, the method of contacting may be accomplished by spraying, flushing, wiping with a substrate e.g., wiping cloth or paper, that has the cleaning composition incorporated in or on it. In another embodiment of the present disclosure, the method of contacting may be accomplished by dipping or immersing the article in a bath of the cleaning composition.

In one embodiment of the present disclosure, the process of recovering is accomplished by removing the surface that has been contacted from the cleaning composition bath (in a similar manner as described for the method for depositing a fluorolubricant on a surface as described below). In another embodiment of the invention, the process of recovering is accomplished by allowing the cleaning composition that has been sprayed, flushed, or wiped on the disk to drain away. Additionally, any residual cleaning composition that may be left behind after the completion of the previous steps may be evaporated in a manner similar to that for the deposition method.

The method for cleaning a surface may be applied to the same types of surfaces as the method for deposition as described below. Semiconductor surfaces or magnetic media disks of silica, glass, metal or metal oxide, or carbon may have contaminants removed by the process of the invention. In the method described above, contaminant may be removed from a disk by contacting the disk with the cleaning composition and recovering the disk from the cleaning composition.

In yet another embodiment, the present method also provides methods of removing contaminants from a product, part, component, substrate, or any other article or portion thereof by contacting the article with a cleaning composition of the present disclosure. As referred to herein, the term “article” refers to all such products, parts, components, substrates, and the like and is further intended to refer to any surface or portion thereof.

As used herein, the term “contaminant” is intended to refer to any unwanted material or substance present on the article, even if such substance is placed on the article intentionally. For example, in the manufacture of semiconductor devices it is common to deposit a photoresist material onto a substrate to form a mask for the etching operation and to subsequently remove the photoresist material from the substrate. The term “contaminant,” as used herein, is intended to cover and encompass such a photo resist material. Hydrocarbon based oils and greases and dioctylphthalate are examples of the contaminants that may be found on the carbon coated disks.

In one embodiment, the method of the invention comprises contacting the article with a cleaning composition of the invention, in a vapor degreasing and solvent cleaning method. In one such embodiment, vapor degreasing and solvent cleaning methods consist of exposing an article, preferably at room temperature, to the vapors of a boiling cleaning composition. Vapors condensing on the object have the advantage of providing a relatively clean, distilled cleaning composition to wash away grease or other contamination. Such processes thus have an additional advantage in that final evaporation of the present cleaning composition from the object leaves behind relatively little residue as compared to the case where the object is simply washed in liquid cleaning composition.

In another embodiment, for applications in which the article includes contaminants that are difficult to remove, the method of the invention involves raising the temperature of the cleaning composition above ambient temperature or to any other temperature that is effective in such application to substantially improve the cleaning action of the cleaning composition. In one such embodiment, such processes are also generally used for large volume assembly line operations where the cleaning of the article, particularly metal parts and assemblies, must be done efficiently and quickly.

In one embodiment, the cleaning methods of the present disclosure comprise immersing the article to be cleaned in liquid cleaning composition at an elevated temperature. In another embodiment, the cleaning methods of the present disclosure comprise immersing the article to be cleaned in liquid cleaning composition at about the boiling point of the cleaning composition. In one such embodiment, this step removes a substantial amount of the target contaminant from the article. In yet another embodiment, this step removes a major portion of the target contaminant from the article. In one embodiment, this step is then followed by immersing the article in freshly distilled cleaning composition, which is at a temperature below the temperature of the liquid cleaning composition in the preceding immersion step. In one such embodiment, the freshly distilled cleaning composition is at about ambient or room temperature. In yet another embodiment, the method also includes the step of then contacting the article with relatively hot vapor of the cleaning composition by exposing the article to vapors rising from the hot/boiling cleaning composition associated with the first mentioned immersion step. In one such embodiment, this results in condensation of the cleaning composition vapor on the article. In certain preferred embodiments, the article may be sprayed with distilled cleaning composition before final rinsing.

It is contemplated that numerous varieties and types of vapor degreasing equipment are adaptable for use in connection with the present methods. One example of such equipment and its operation is disclosed by U.S. Pat. No. 3,085,918, which is incorporated herein by reference. The equipment disclosed therein includes a boiling sump for containing a cleaning composition, a clean sump for containing distilled cleaning composition, a water separator, and other ancillary equipment.

The present cleaning methods may also comprise cold cleaning in which the contaminated article is either immersed in the fluid cleaning composition of the present disclosure under ambient or room temperature conditions or wiped under such conditions with rags or similar objects soaked in the cleaning composition.

Another embodiment relates to a method of depositing a fluorolubricant on a surface comprising: (a) combining a fluorolubricant and a solvent, said solvent comprising methyl perfluoropentene ethers and at least one of methanol, ethanol, 2-propanol, hexane, heptane, trans-1,2-dichloroethylene, ethyl formate, methyl formate, HFE-7100, HFE-7200 and 1-bromopropane or combinations thereof; (b) contacting the combination of lubricant-solvent with the surface; and (c) evaporating the solvent from the surface to form a fluorolubricant coating on the surface.

In one embodiment of the invention, the fluorolubricants of the present disclosure comprise perfluoropolyether (PFPE) compounds, or a lubricant comprising X-1P®, which is a phosphazene-containing disk lubricant. These perfluoropolyether compounds are sometimes referred to as perfluoroalkylethers (PFAE) or perfluoropolyalkylethers (PFPAE). These PFPE compounds range from simple perfluorinated ether polymers to functionalized perfluorinated ether polymers. PFPE compounds of different varieties that may be useful as fluorolubricant in the present disclosure are available from several sources.

In another embodiment, useful fluorolubricants for the present inventive method include but are not limited to Krytox® GLP 100, GLP 105 or GLP 160 (E. I. du Pont de Nemours & Co., Fluoroproducts, Wilmington, Del., 19898, USA); Fomblin® Z-Dol 2000, 2500 or 4000, Z-Tetraol, or Fomblin® AM 2001 or AM 3001 (sold by Solvay Solexis S.p.A., Milan, Italy); Demnum™ LR-200 or S-65 (offered by Daikin America, Inc., Osaka, Japan); X-1P® (a partially fluorinated hyxaphenoxy cyclotriphosphazene disk lubricant available from Quixtor Technologies Corporation, a subsidiary of Dow Chemical Co, Midland, Mich.); and mixtures thereof.

The Krytox® lubricants are perfluoroalkylpolyethers having the general structure F(CF(CF₃)CF₂O)ₙ—CF₂CF₃, wherein n ranges from 10 to 60. The Fomblin® lubricants are functionalized perfluoropolyethers that range in molecular weight from 500 to 4000 atomic mass units and have general formula X—CF₂—O(CF₂—CF₂—O)ₚ—(CF₂O)_{q}—CF₂—X, wherein X may be —CH₂OH, CH₂(O—CH₂—CH₂)ₙOH, CH₂OCH₂CH(OH)CH₂OH or —CH₂O—CH₂-piperonyl. The Demnum™ oils are perfluoropolyether-based oils ranging in molecular weight from 2700 to 8400 atomic mass units. Additionally, new lubricants are being developed such as those from Moresco (Thailand) Co., Ltd, which may be useful in the present inventive method.

The fluorolubricants of the present disclosure may additionally comprise additives to improve the properties of the fluorolubricant. X-1P®, which may serve as the lubricant itself, is often added to other lower cost fluorolubricants in order to increase the durability of disk drives by passivating Lewis acid sites on the disk surface responsible for PFPE degradation. Other common lubricant additives may be used in the fluorolubricants of the present inventive methods.

The fluorolubricants of the present disclosure may further comprise Z-DPA (Hitachi Global Storage Technologies, San Jose, Calif.), a PFPE terminated with dialkylamine end-groups. The nucleophilic end-groups serve the same purpose as X1P®, thus providing the same stability without any additive.

The surface on which the fluorolubricant may be deposited is any solid surface that may benefit from lubrication. Semiconductor materials such as silica disks, metal or metal oxide surfaces, vapor deposited carbon surfaces or glass surfaces are representative of the types of surfaces for which the methods of the present disclosure are useful. The present inventive method is particularly useful in coating magnetic media such as computer drive hard disks. In the manufacture of computer disks, the surface may be a glass, or aluminum substrate with layers of magnetic media that is also coated by vapor deposition with a thin (10-50 Angstrom) layer of amorphous hydrogenated or nitrogenated carbon. The fluorolubricant may be deposited on the surface disk indirectly by applying the fluorolubricant to the carbon layer of the disk.

The first step of combining the fluorolubricant and solvent (“fluorolubricant/solvent combination”) may be accomplished in any suitable manner such as mixing in a suitable container such as a beaker or other container that may be used as a bath for the deposition method. The fluorolubricant concentration in the unsaturated fluorinated ether solvent may be from about 0.010 percent (wt/wt) to about 0.50 percent (wt/wt).

The step of contacting the fluorolubricant/solvent combination with the surface may be accomplished in any manner appropriate for the surface, based on the size and shape of the surface. A hard drive disk must be supported in some manner such as with a mandrel or some other support that may fit through the hole in the center of the disk. The disk will thus be held vertically such that the plane of the disk is perpendicular to the solvent bath. The mandrel may have different shapes including, but not limited to, a cylindrical bar, or a V-shaped bar. The mandrel shape will determine the area of contact with the disk. The mandrel may be constructed of any material strong enough to hold the disk, including but not limited to metal, metal alloy, plastic or glass. Additionally, a disk may be supported vertically upright in a woven basket or be clamped into a vertical position with 1 or more clamps on the outer edge. The support may be constructed of any material with the strength to hold the disk, such as metal, metal alloy, plastic or glass. However the disk is supported, the disk will be lowered into a container holding a bath of the fluorolubricant/solvent combination. The bath may be held at room temperature or be heated or cooled to temperatures ranging from about 0° C. to about 50° C.

Alternatively, the disk may be supported as described above and the bath may be raised to immerse the disk. In either case, the disk may then be removed from the bath, either by lowering the bath or by raising the disk. Excess fluorolubricant/solvent combination can be drained into the bath.

Either of the methods for contacting the fluorolubricant/solvent combination with the disk surface of either lowering the disk into a bath or raising a bath to immerse the disk are commonly referred to as dip coating. Other methods for contacting the disk with the fluorolubricant/solvent combination may be used in the present disclosure, including spraying or spin coating.

When the disk is removed from the bath, the disk will have a coating of fluorolubricant and some residual solvent (unsaturated fluorinated ether) on its surface. The residual solvent may be evaporated. Evaporation is usually performed at room temperature. However, other temperatures both above and below room temperature may be used as well for the evaporation step. Temperatures ranging from about 0° C. to about 100° C. may be used for evaporation.

The surface, or the disk if the surface is a disk, after completion of the coating method, will be left with a substantially uniform or uniform coating of fluorolubricant that is substantially free of solvent. The fluorolubricant may be applied to a thickness of less than about 300 nm, and alternately to a thickness of about 100 to about 300 nm.

A uniform fluorolubricant coating is desired for proper functioning of a disk and so areas of varying fluorolubricant thickness are undesirable on the surface of the disk. As more and more information is being stored on the same size disk, the read/write head must get closer and closer to the disk in order to function properly. If irregularities due to variation in coating thickness are present on the surface of the disk, the probability of contact of the head with these areas on the disk is much greater. While there is a desire to have enough fluorolubricant on the disk to flow into areas where it may be removed by head contact or other means, coating that is too thick may cause “smear,” a problem associated with the read/write head picking up excess fluorolubricant.

One specific coating thickness irregularity observed in the industry is that known as the “rabbit ears” effect. These irregularities are visually detected on the surface of the disk after deposition of the fluorolubricant using the existing solvent systems. When the disk is contacted with the solution of fluorolubricant in solvent and then removed from the solution, any points where the solution may accumulate and not drain readily develop drops of solution that do not readily drain off. One such point of drop formation is the contact point (or points) with the mandrel or other support device with the disk. When a V-shaped mandrel is used, there are two contact points at which the mandrel contacts the inside edge of the disk. When solution of fluorolubricant forms drops in these locations that do not drain off when removed from the bath, an area of greater thickness of fluorolubricant is created when the solvent evaporates. The two points of contact with the disk produces what is known as a “rabbit ears” effect, because the areas of greater fluorolubricant thickness produce a pattern resembling rabbit ears visually detectable on the disk surface.

When dip coating is used for depositing fluorolubricant on the surface, the pulling-up speed (speed at which the disk is removed from the bath), and the density of the fluorolubricant and the surface tension are relevant for determining the resulting film thickness of the fluorolubricant. Awareness of these parameters for obtaining the desired film thickness is required. Details on how these parameters affect coatings are given in, “Dip-Coating of Ultra-Thin Liquid Lubricant and its Control for Thin-Film Magnetic Hard Disks” in IEEE Transactions on Magnetics, vol. 31, no. 6, November 1995.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

### EXAMPLES

The concepts described herein will be further described in the following examples, which do not limit the scope of the invention described in the claims.

### Example 1

Example 1 demonstrates that distillation of a mixture of trans-1,2-dichloroethylene, MPPE and iso-propanol.

A blend of approximately 40 wt % MPPE, 57 wt % trans-1,2-dichloroethylene (t-DCE) and 3 wt % IPA was prepared. The blend was distilled in a 5-plate Oldershaw distillation column using a 10:1 reflux to take-off ratio. Column overhead and flask temperatures were recorded to the nearest 0.1 degree. Distillate samples were taken throughout the experiment to determine composition by Gas Chromatography. The results are shown in Table 5.

TABLE 5

| | Volume | | Head | | | |
|---|---|---|---|---|---|---|
| | distilled | Pot temp | temp. | MPPE | t-DCE | IPA (wt |
| Cut | (%) | (° C.) | (° C.) | (wt %) | (wt %) | %) |
| Initial | Initial | 46.6 | 45.6 | 38.2 | 58.8 | 3.0 |
| 1 | 10 | 46.7 | 45.7 | 38.1 | 59.9 | 2.0 |
| 2 | 20 | 46.8 | 45.8 | 36.9 | 61.1 | 2.0 |
| 3 | 30 | 47.0 | 45.7 | 37.4 | 60.7 | 1.9 |
| 4 | 40 | 47.3 | 45.8 | 35.7 | 62.3 | 2.1 |
| 5 | 50 | 47.7 | 45.9 | 34.6 | 63.3 | 2.1 |
| 6 | 60 | 47.7 | 45.9 | 33.7 | 64.1 | 2.2 |
| 7 | 80 | 62.4 | 47.0 | 32.3 | 64.6 | 3.1 |
| heel | — | — | — | 74.8 | 16.2 | 9.0 |

Analysis of the above data indicates small differences between head temperatures and distillate compositions as the distillation progressed. The data indicates the binary azeotrope of MPPE, tDCE and isopropanol is 35.5+/−2.1 wt % MPPE, 62.3+/−1.8 wt % tDCE and 2.2+/−0.4 wt % isopropanol, with a boiling point of 45.8+/−0.1° C. at atmospheric pressure.

### Example 2

Example 2 demonstrates removal of oil from samples with various mixtures of MPPE and trans-1,2-dichloroethylene.

Mineral oil was wiped onto pre-cleaned metal coupons, of known weights, with a swab. The coupons were weighed again and then cleaned by immersion into the boiling solvent compositions below. Coupons were immersed for 3 minutes and air dried. The coupons were then reweighed and the percent of oil removed was determined. These results show that the solvents have excellent efficiency in cleaning mineral oils. Results are summarized in tables 6-8.
Solvent Composition: 38 wt % MPPE and 62 wt % 1,2-trans-dichloroethylene

TABLE 6

| | | Oil-contaminated wt | Cleaned | % |
|---|---|---|---|---|
| Coupon | Tare wt (g) | (g) | wt (g) | removed |
| 1 | 21.5155 | 21.5726 | 21.5155 | 100 |
| 2 | 19.0212 | 19.0907 | 19.0212 | 100 |
| 3 | 21.2879 | 21/3807 | 21.2879 | 100 |

Solvent Composition: 36 wt % MPPE, 62 wt % 1,2-trans-dichloroethylene and 2 wt % isopropanol

TABLE 7

| | | Oil- | | |
|---|---|---|---|---|
| | | contaminated | Cleaned wt | |
| Coupon | Tare wt (g) | wt (g) | (g) | % removed |
| 1 | 21.5155 | 21.5446 | 21.5155 | 100 |
| 2 | 21.2881 | 21.3606 | 21.2881 | 100 |
| 3 | 19.0211 | 19.0716 | 19.0212 | 99.8 |

Solvent Composition: 20 wt % MPPE and 60 wt % 1,2-trans-dichloroethylene and 20% HFC=365mfc

TABLE 8

| | | Oil- | | |
|---|---|---|---|---|
| | | contaminated | Cleaned wt | |
| Coupon | Tare wt (g) | wt (g) | (g) | % removed |
| 1 | 19.0212 | 19.0887 | 19.0212 | 100 |
| 2 | 21.5155 | 21.5746 | 21.5255 | 100 |
| 3 | 21.2878 | 21.3527 | 21.3527 | 100 |

### Example 3

A blend of approximately 38 wt % MPPE and 62 wt % trans-1,2-dichloroethylene (t-DCE) was prepared. The blend was distilled in a 5-plate Oldershaw distillation column using a 10:1 reflux to take-off ratio. Column overhead and flask temperatures were recorded to the nearest 0.1 degree. Distillate samples were taken throughout the experiment to determine composition by Gas Chromatography. The results are shown in Table 9.

TABLE 9

| | Volume | Flask | Head | Wt % | Wt % t- |
|---|---|---|---|---|---|
| Cut | distilled | temp | temp | MPPE | DCE |
| initial | 0% | 45.4 | 45.3 | 38.1 | 61.9 |
| 1 | 10% | 45.6 | 45.2 | 41.5 | 58.5 |
| 2 | 20% | 45.7 | 45.3 | 40.5 | 59.5 |
| 3 | 30% | 45.6 | 45.3 | 39.4 | 60.6 |
| 4 | 40% | 45.7 | 45.4 | 38.6 | 61.4 |
| 5 | 50% | 46.7 | 44.6 | 35.2 | 64.8 |
| 6 | 60% | 46.5 | 44.7 | 33.8 | 66.2 |
| 7 | 80% | 47 | 44.6 | 32.2 | 67.8 |
| heel | | | | 42.6 | 57.4 |

Analysis of the above data indicates small differences between head temperatures and distillate compositions as the distillation progressed. The data indicates the binary azeotrope is 37.3+/−3.6 wt % MPPE and 62.7+/−3.6 wt % tDCE , with a boiling point of 46.0+/−0.5 deg C. at atmospheric pressure.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. An azeotropic or azeotrope-like compositions comprising methyl perfluoropentene ethers and at least one of methanol, ethanol, 2-propanol, hexane, heptane, trans-1,2-dichloroethylene, ethyl formate, methyl formate, HFE-7100, HFE-7200 and 1-bromopropane or combinations thereof.

2. An azeotropic or azeotrope-like composition as in claim 1, wherein the compositions comprises an azeotropic or azeotrope-like composition selected from the group consisting of:
about 14 to about 68 percent by weight of methyl perfluoropentene ethers and about 32 to about 86 percent by weight of trans-1,2-dichloroethylene;
about 72 to about 95 percent by weight of methyl perfluoropentene ethers and about 5 to about 28 percent by weight methanol;
about 72 to about 96 percent by weight of methyl perfluoropentene ethers and about 4 to about 28 percent by weight ethanol;
about 70 to about 95 percent by weight of methyl perfluoropentene ethers and about 5 to about 30 percent by weight 2-propanol;
about 1 to about 99 percent by weight of methyl perfluoropentene ethers and about 1 to about 9 percent by weight hexane;
about 1 to about 15 percent by weight of methyl perfluoropentene ethers and about 85 to about 99 percent by weight n-heptane;
about 85 to about 99 percent by weight of methyl perfluoropentene ethers and about 1 to about 15 percent by weight n-heptane;
about 1 to about 73 percent by weight of methyl perfluoropentene ethers and about 27 to about 99 percent by weight cyclopentane;
about 26 to about 79 percent by weight of methyl perfluoropentene ethers and about 21 to about 74 percent by weight methyl formate;
about 33 to about 79 percent by weight of methyl perfluoropentene ethers and about 21 to about 67 percent by weight ethyl formate;
about 1 to about 99 percent by weight of methyl perfluoropentene ethers and about 1 to about 99 percent by weight HFE-7100;
about 1 to about 99 percent by weight of methyl perfluoropentene ethers and about 1 to about 99 percent by weight HFE-7200;
about 39 to about 83 percent by weight of methyl perfluoropentene ethers and about 17 to about 61 percent by weight 1-bromopropane.

3. An azeotropic composition as in claim 1, wherein the composition comprises an azeotropic composition selected from the group consisting of:
about 87.1 weight percent methyl perfluoropentene ethers and 12.9 weight percent methanol having a vapor pressure of about 14.7 psia (101 kPa) at a temperature of about 43.4° C.;
88.9 weight percent methyl perfluoropentene ethers and 11.1 weight percent ethanol having a vapor pressure of about 14.7 psia (101 kPa) at a temperature of about 57.7° C.;
87.9 weight percent methyl perfluoropentene ethers and 12.1 weight percent 2-propanol having a vapor pressure of about 14.7 psia (101 kPa) at a temperature of about 59.7° C.;
37.7 weight percent methyl perfluoropentene ethers and 62.3 weight percent trans-1,2-dichloroethylene having a vapor pressure of about 14.7 psia (101 kPa) at a temperature of about 43.3° C.;
18.4 weight percent methyl perfluoropentene ethers and 71.6 weight percent cyclopentane having a vapor pressure of about 14.7 psia (101 kPa) at a temperature of about 49.1° C.;
42.2 weight percent methyl perfluoropentene ethers and 57.8 weight percent methyl formate having a vapor pressure of about 14.7 psia (101 kPa) at a temperature of about 29.2° C.;
54.7 weight percent methyl perfluoropentene ethers and 45.3 weight percent ethyl formate having a vapor pressure of about 14.7 psia (101 kPa) at a temperature of about 46.3° C.;
62.8 weight percent methyl perfluoropentene ethers and 37.2 weight percent n-propylbromide having a vapor pressure of about 14.7 psia (101 kPa) at a temperature of about 57.3° C.;

4. An azeotropic composition as in claim 1, wherein the composition consists essentially of an azeotropic or azeotrope-like composition selected from the group consisting of:
about 14 to about 68 percent by weight of methyl perfluoropentene ethers and about 32 to about 86 percent by weight of trans-1,2-dichloroethylene;
about 72 to about 95 percent by weight of methyl perfluoropentene ethers and about 5 to about 28 percent by weight methanol;
about 72 to about 96 percent by weight of methyl perfluoropentene ethers and about 4 to about 28 percent by weight ethanol;
about 70 to about 95 percent by weight of methyl perfluoropentene ethers and about 5 to about 30 percent by weight 2-propanol;
about 1 to about 99 percent by weight of methyl perfluoropentene ethers and about 1 to about 9 percent by weight hexane;
about 1 to about 15 percent by weight of methyl perfluoropentene ethers and about 85 to about 99 percent by weight n-heptane;
about 85 to about 99 percent by weight of methyl perfluoropentene ethers and about 1 to about 15 percent by weight n-heptane;
about 1 to about 73 percent by weight of methyl perfluoropentene ethers and about 27 to about 99 percent by weight cyclopentane;
about 26 to about 79 percent by weight of methyl perfluoropentene ethers and about 21 to about 74 percent by weight methyl formate;
about 33 to about 79 percent by weight of methyl perfluoropentene ethers and about 21 to about 67 percent by weight ethyl formate;
about 1 to about 99 percent by weight of methyl perfluoropentene ethers and about 1 to about 99 percent by weight HFE-7100;
about 1 to about 99 percent by weight of methyl perfluoropentene ethers and about 1 to about 99 percent by weight HFE-7200; and
about 39 to about 83 percent by weight of methyl perfluoropentene ethers and about 17 to about 61 percent by weight 1-bromopropane.

5. An azeotropic composition as in claim 1, wherein the composition consists essentially of an azeotropic composition selected from the group consisting of:
about 87.1 weight percent methyl perfluoropentene ethers and 12.9 weight percent methanol having a vapor pressure of about 14.7 psia (101 kPa) at a temperature of about 43.4° C.;
88.9 weight percent methyl perfluoropentene ethers and 11.1 weight percent ethanol having a vapor pressure of about 14.7 psia (101 kPa) at a temperature of about 57.7° C.;
87.9 weight percent methyl perfluoropentene ethers and 12.1 weight percent 2-propanol having a vapor pressure of about 14.7 psia (101 kPa) at a temperature of about 59.7° C.;
37.7 weight percent methyl perfluoropentene ethers and 62.3 weight percent trans-1,2-dichloroethylene having a vapor pressure of about 14.7 psia (101 kPa) at a temperature of about 43.3° C.;
18.4 weight percent methyl perfluoropentene ethers and 71.6 weight percent cyclopentane having a vapor pressure of about 14.7 psia (101 kPa) at a temperature of about 49.1° C.;
42.2 weight percent methyl perfluoropentene ethers and 57.8 weight percent methyl formate having a vapor pressure of about 14.7 psia (101 kPa) at a temperature of about 29.2° C.;
54.7 weight percent methyl perfluoropentene ethers and 45.3 weight percent ethyl formate having a vapor pressure of about 14.7 psia (101 kPa) at a temperature of about 46.3° C.;
62.8 weight percent methyl perfluoropentene ethers and 37.2 weight percent n-propylbromide having a vapor pressure of about 14.7 psia (101 kPa) at a temperature of about 57.3° C.;

6. The composition of claim 2 further comprising an aerosol propellant.

7. The composition of claim 6, wherein said propellant is comprised of air, nitrogen, carbon dioxide, 2,3,3,3-tetrafluoropropene, trans-1,3,3,3-tetrafluoropropene, 1,2,3,3,3-pentafluoropropene, difluoromethane, trifluoromethane, difluoroethane, trifluoroethane, tetrafluoroethane, pentafluoroethane, hydrocarbons, or dimethyl ether, or combinations thereof.

8. The composition of claim 2, wherein said composition further comprises at least one surfactant.

9. A process for cleaning, comprising:
a. contacting a surface comprising a residue with the composition of claim 1 and
b. removing the surface from the composition.

10. The method of claim 9, wherein said contacting is accomplished by vapor degreasing.

11. The method of claim 10, wherein said vapor degreasing is performed by:
a. boiling the composition; and
b. exposing the article to vapors of said composition.

12. The method of claim 9, wherein said contacting is accomplished by a first step of immersing the article in said composition, wherein the composition is at a temperature greater than ambient temperature or room temperature.

13. The method of claim 12, wherein the composition is at a temperature of about the boiling point of the composition.

14. The method of claim 12, further comprising a second step of immersing the article in said composition, wherein said composition is at a temperature lower than the temperature of the first immersing step.

15. The method of claim 14, wherein the composition in the second immersing step is at ambient temperature or room temperature.

16. The method of claim 14, further comprising the steps of boiling the composition and exposing the article to vapors of the boiling composition.

17. The method of claim 9, wherein the composition is at ambient temperature or room temperature.

18. The method of claim 9, wherein said contacting is accomplished by wiping the surface with an object saturated with the composition.

19. A method for depositing a fluorolubricant on a surface of an article comprising:
a. combining a fluorolubricant and a solvent, thereby forming a mixture, said solvent comprising the composition of claim 1;
b. contacting said mixture with the surface of said article; and
c. evaporating the solvent from the surface of said article to form a fluorolubricant coating on the surface.

20. The method of claim 19, wherein the surface comprises a semiconductor material, metal, metal oxide, vapor deposited carbon, or glass, or combinations thereof.

21. The method of claim 20, wherein the surface comprises a magnetic medium.

22. The method of claim 21, wherein the magnetic medium is a computer disk.

23. The method of claim 19, wherein said contacting is accomplished by dipping or immersing the surface in a bath comprising the fluorolubricant and solvent.

24. The method of claim 19, wherein the contacting step is accomplished by spraying or spin coating the surface with the fluorolubricant and solvent.

25. The method of claim 19, wherein the fluorolubricant concentration in the lubricant-solvent mixture is from about 0.02 weight percent to about 0.5 weight percent.

26. The method of claim 19, wherein the evaporating step is accomplished at a temperature of from about 10° C. to about 40° C.

27. The method of claim 19, wherein the fluorolubricant comprises a perfluoropolyether.

28. The method of claim 19, wherein the fluorolubricant comprises perfluoropolyethers or mixtures thereof.
